(19) United States
(12) Patent Application Publication
(10) Pub. No.: US 2020/0075861 A1
(43) Pub. Date: Mar. 5, 2020

(54) RESIN SUBSTRATE LAMINATE AND MANUFACTURING METHOD FOR ELECTRONIC DEVICE

(71) Applicant: GEOMATEC CO., LTD., Kanagawa (JP)

(72) Inventor: Hiroyuki SUGAWARA, Miyagi (JP)

(21) Appl. No.: 16/492,771

(22) PCT Filed: Sep. 20, 2018
(86) PCT No.: PCT/JP2018/034926

§ 371 Date: Sep. 10, 2019

(30) Foreign Application Priority Data
Sep. 22, 2017 (JP) 2017-182893

(51) Int. Cl. H01L 51/00; C23C 14/06; C23C 14/35; C03C 17/42; H01G 9/20; G02F 1/1333

(52) U.S. Cl. CPC H01L 51/003; C23C 14/0635; C23C 14/35; C03C 17/42; H01L 51/0097; H01L 2251/5338; G02F 1/133305; C03C 2218/156; C03C 2218/116; C03C 2218/328; H01G 9/2095

(57) ABSTRACT

Provided are a resin substrate laminate which enables a resin substrate to be easily released from a release layer by a brief light irradiation process using a low-energy laser beam, and a method for manufacturing an electronic device using the resin substrate laminate. The resin substrate laminate includes a release layer-attached support substrate 4, which has a support substrate 1 and a release layer 2 laminated on the support substrate 1, and a resin substrate 3 which is releasably laminated on a surface, which is opposite to the support substrate 1, of the release layer 2, in which a composition of a surface of the release layer 2 is SiₓC_{y}O_{z} (0.05≤x≤0.49, 0.15≤y≤0.73, 0.22≤z≤0.36, x+y+z=1).

### TECHNICAL FIELD

The present invention relates to a resin substrate laminate and a method for manufacturing an electronic device using the resin substrate laminate.

### BACKGROUND ART

In recent years, electronic devices such as an organic EL display (OLED), a liquid crystal panel (LCD), and a photovoltaic cell (PV) have been getting thinner and lighter. Further, bending functionality, that is, flexibility has been desired to be provided to these electronic devices. Under such a background, instead of conventional glass substrates that are heavy and cannot be bent, resin substrates that are light and flexible have been used.

In manufacturing processes of these electronic devices, a substrate laminate is used in which a release layer containing inorganic matters or organic matters is formed on a support substrate and a glass substrate or a resin substrate is releasably laminated on the release layer. Specifically, an electronic component is formed on the glass substrate or the resin substrate of the substrate laminate, and then, the electronic component-attached glass substrate or resin substrate is released from the release layer, thereby manufacturing an electronic device.

PATENT LITERATURE 1 describes a method for manufacturing an electronic device, the method of using a glass laminate including a support substrate, an inorganic layer-attached support substrate which includes an inorganic layer disposed on the support substrate, and a glass substrate releasably laminated on the inorganic layer and physically releasing the glass substrate.

PATENT LITERATURE 2 describes a method for producing a display device, the method of forming a resin substrate on a fixed substrate with an amorphous silicon film interposed therebetween, forming a TFT element on the resin substrate, and then irradiating the amorphous silicon film with a laser beam to release the resin substrate from the fixed substrate.

PATENT LITERATURE 3 describes a release layer formed by using a composition for forming a release layer, the composition containing a polyamic acid introduced with an anchor group at the polymer chain terminal end thereof and an organic solvent.

### CITATION LIST

### Patent Literature

PATENT LITERATURE 1: JP 5991373 B2
PATENT LITERATURE 2: JP 5147794 B2
PATENT LITERATURE 3: WO 2016/158990 A

### SUMMARY OF INVENTION

### Technical Problem

In the case of the release layer of the related art, it is necessary to irradiate the release layer with high-energy ultraviolet rays for a long time when the substrate on the release layer is released. Further, in the case of using the resin substrate, when high-energy ultraviolet rays are irradiated, the resin substrate may be modified by heat.

The present invention has been made in view of the above-described problems, and an object of the present invention is to provide a resin substrate laminate which enables a resin substrate to be easily released from a release layer by a brief light irradiation process using a low-energy laser beam, and a method for manufacturing an electronic device using the resin substrate laminate.

### Solution to Problem

The above-described problems are solved by a resin substrate laminate of the present invention including a release layer-attached support substrate which has a support substrate and a release layer laminated on the support substrate, and a resin substrate which is releasably laminated on a surface, which is opposite to the support substrate, of the release layer, in which a composition of a surface of the release layer is SiₓC_{y}O_{z} (0.05≤x≤0.49, 0.15≤y≤0.73, 0.22≤z≤0.36, x+y+z=1).

With the above-described configuration, since the resin substrate can be easily released from the release layer by the brief light irradiation process using the low-energy laser beam, when the resin substrate laminate is used in manufacturing of an electronic device, productivity is improved and manufacturing cost can be reduced.

At this time, it is preferable that the composition of the surface of the release layer is SiₓC_{y}O_{z} (0.05≤x≤0.43, 0.27≤y≤0.73, 0.22≤z≤0.30, x+y+z=1).

As described above, by controlling the composition of the surface of the release layer to a proper range, releasability by laser beam irradiation can be improved and a damage of the resin substrate or deterioration of the release layer caused by a laser beam can be suppressed.

At this time, it is preferable that the release layer is in an amorphous state.

As described above, when the release layer is in an amorphous state, the release layer can be formed by a simple method such as sputtering, and releasability can be improved.

At this time, it is preferable that the release layer is formed by a material which enables the resin substrate to be released from the release layer by irradiation of a laser beam having a wavelength of 355 nm.

As described above, the release layer has an absorption band near a wavelength of 355 nm and general YAG laser can be used.

At this time, it is preferable that the release layer is formed by a material which enables the resin substrate to be released from the release layer by irradiation of a laser beam having a wavelength of 355 nm at an intensity of 60 to 80 mJ/cm².

As described above, the release layer has an absorption band near a wavelength of 355 nm and general YAG laser can be used. In addition, the resin substrate can be properly released even in low-energy laser beam irradiation.

The above-described problems are solved by a method for manufacturing an electronic device of the present invention, the method including a step of preparing a resin substrate laminate by laminating a release layer on a support substrate using a target having a ratio of Si:C of 10:90 to 90:10 and laminating a resin substrate on a surface, which is opposite to the support substrate, of the release layer, a member forming step of forming an electronic device member on a surface of the resin substrate of the resin substrate laminate, and a releasing step of releasing the resin substrate from the release layer by irradiating the release layer with a laser beam.

As described above, since the resin substrate can be easily released from the release layer by the brief light irradiation process using the low-energy laser beam, productivity when an electronic device is manufactured is improved and manufacturing cost can be reduced.

At this time, it is preferable that the ratio of Si:C in the target is 30:70 to 90:10.

As described above, by controlling the composition of the surface of the release layer to a proper range, releasability by laser beam irradiation can be improved and a damage of the resin substrate or deterioration of the release layer caused by a laser beam can be suppressed.

At this time, it is preferable that the release layer is in an amorphous state.

As described above, when the release layer is in an amorphous state, the release layer can be formed by a simple method such as sputtering, and releasability can be improved.

At this time, it is preferable that in the releasing step, a laser beam having a wavelength of 355 nm is irradiated.

As described above, the release layer has an absorption band near a wavelength of 355 nm and general YAG laser can be used.

At this time, it is preferable that in the releasing step, a laser beam having a wavelength of 355 nm is irradiated at an intensity of 60 to 80 mJ/cm².

As described above, the release layer has an absorption band near a wavelength of 355 nm and general YAG laser can be used. In addition, the resin substrate can be properly released even in low-energy laser beam irradiation.

### Advantageous Effects of Invention

Since the release layer is formed by SiₓC_{y}O_{z}(0.05≤x≤0.49, 0.15≤y≤0.73, 0.22≤z≤0.36, x+y+z=1) in the resin substrate laminate of the present invention, the resin substrate can be easily released from the release layer by the brief light irradiation process using the low-energy laser beam. Therefore, when the resin substrate laminate of the present invention is used in manufacturing of an electronic device, productivity is improved and manufacturing cost can be reduced.

Further, since the resin substrate can be easily released from the release layer by the brief light irradiation process using the low-energy laser beam in the resin substrate laminate of the present invention, releasing can be performed without the resin substrate being damaged.

Furthermore, when the resin substrate is laminated again after releasing the resin substrate in the resin substrate laminate of the present invention, the resin substrate laminate can be reused.

### BRIEF DESCRIPTION OF DRAWINGS

FIG. 1 is a schematic cross-sectional view illustrating a resin substrate laminate according to an embodiment of the present invention.

FIG. 2 is a schematic cross-sectional view illustrating an electronic device member-attached laminate having an electronic device member formed on the resin substrate laminate according to the embodiment of the present invention.

FIG. 3 is a schematic cross-sectional view illustrating a state where an electronic device is released from a release layer-attached support substrate in the electronic device member-attached laminate according to the embodiment of the present invention.

FIG. 4 is a flowchart of a method for manufacturing an electronic device according to an embodiment of the present invention.

FIG. 5 is a graph showing a result of composition analysis of a glass substrate/a SiC film before irradiation of a laser beam.

FIG. 6 is a graph showing a result of composition analysis of the glass substrate/the SiC film after irradiation of a laser beam (100 mJ).

FIG. 7 is a graph showing X-ray diffraction patterns of resin substrate laminates of Examples 3-1 to 3-5 and Reference Examples 3-1 and 3-2.

FIG. 8 is a graph showing a measurement result of transmissivity of the resin substrate laminates of Examples 3-1 to 3-5 and Reference Examples 3-1 and 3-2 in 300 to 400 nm.

FIG. 9 is a graph showing a measurement result of reflectance of the resin substrate laminates of Examples 3-1 to 3-5 and Reference Examples 3-1 and 3-2 in 300 to 400 nm.

FIG. 10 is a graph showing a measurement result of absorptance of the resin substrate laminates of Examples 3-1 to 3-5 and Reference Examples 3-1 and 3-2 in 300 to 400 nm.

FIG. 11 is a graph showing absorptance of only release layers of the resin substrate laminates of Examples 3-1 to 3-5 and Reference Examples 3-1 and 3-2 in 300 to 400 nm.

### DESCRIPTION OF EMBODIMENTS

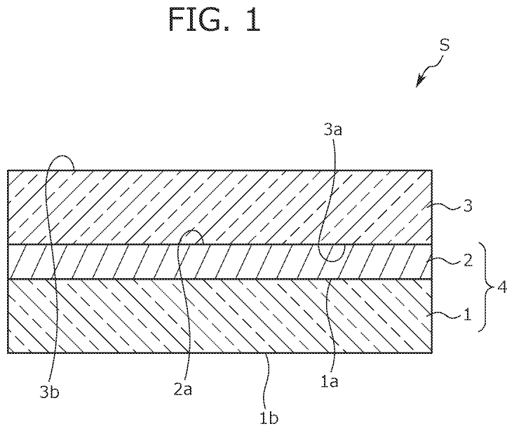

Hereinafter, a resin substrate laminate and a method for manufacturing an electronic device using the resin substrate laminate according to an embodiment of the present invention (present embodiment) will be described with reference to FIGS. 1 to 11.

### <Resin Substrate Laminate S>

A resin substrate laminate S of the present embodiment has, as illustrated in a schematic cross-sectional view of FIG. 1, a release layer-attached support substrate 4, which includes a support substrate 1 and a release layer 2, and a resin substrate 3.

In the resin substrate laminate S of the present embodiment, the release layer-attached support substrate 4 and the resin substrate 3 are releasably laminated using a release layer surface 2a (surface opposite to the support substrate 1 side) of the release layer 2 of the release layer-attached support substrate 4 and a first surface 3a of the resin substrate 3 as lamination surfaces.

In other words, one surface of the release layer 2 is fixed to the support substrate 1, the other surface of the release layer 2 is in contact with the first surface 3a of the resin substrate 3, and an interfaces of the release layer 2 and the resin substrate 3 is releasably and closely adhered. That is, the release layer 2 has easy releasability with respect to the first surface 3a of the resin substrate 3.

Hereinafter, the configuration of the resin substrate laminate S will be described in detail.

### (Release Layer-Attached Support Substrate 4)

The release layer-attached support substrate 4 is provided with the support substrate 1 and the release layer 2 laminated on a surface thereof. The release layer 2 is disposed at the outermost side in the release layer-attached support substrate 4 to be releasably and closely adhered to the resin substrate 3 to be described later.

Next, the support substrate 1 and the release layer 2 will be described.

### (Support Substrate 1)

The support substrate 1 is a substrate which has a first surface 1a and a second surface 1b and supports the resin substrate 3 along with the release layer 2 disposed on the first surface 1a.

As the support substrate 1, in a releasing step to be described later, since a laser beam is irradiated from the rear surface of the support substrate 1, a substrate through which a laser beam used in the releasing step is transmitted may be used, and for example, a glass plate, a plastic plate, and the like may be used. However, the support substrate is not limited thereto. From the viewpoint of ease of handleability and low price, a glass plate is preferably used as the support substrate 1.

Examples of the glass plate include quartz glass, high silicate glass (96% silica), soda-lime glass, lead glass, aluminoborosilicate glass, borosilicate glass (Pyrex (registered trademark)), borosilicate glass (alkali-free), borosilicate glass (microsheet), and aluminosilicate glass. Of these, one with a linear expansion coefficient of 5 ppm/K or less is desirable, and as commercially available products, “Corning (registered trademark) 7059,” “Corning (registered trademark) 1737,” or “EAGLE” as glass for liquid crystal manufactured by Corning Incorporated, “AN100” manufactured by AGC Inc., “OA10” manufactured by Nippon Electric Glass Co., Ltd., “AF32” manufactured by Schott AG, “NA32SG” manufactured by AvanStrate Inc., and the like are desirable.

It is desirable that the planar portion of the support substrate 1 is sufficiently flat. Specifically, a P-V value of surface roughness is 50 nm or less, more preferably 20 nm or less, and further preferably 5 nm or less. When the value of surface roughness is large, the adhesion strength between the release layer 2 and the support substrate 1 may possibly become insufficient.

The thickness of the support substrate 1 is selected on the basis of the thickness of the resin substrate 3 to be described later, and the thickness of a final resin substrate laminate S. In the case of using a glass plate as the support substrate 1, the thickness of the support substrate 1 is preferably 10 mm or less, more preferably 3 mm or less, and further preferably 1.3 mm or less in order to have properties that the support substrate is properly bent without being broken when the support substrate is released after an electronic device member is formed. The lower limit of the thickness is not particularly limited, but from the viewpoint of handleability, the thickness is preferably 0.07 mm or more, more preferably 0.15 mm or more, and further preferably 0.3 mm or more.

The area of the support substrate 1 is preferably large from the viewpoint of production efficiency and cost of the release layer-attached support substrate 4, the resin substrate laminate S, and a flexible electronic device. Specifically, the area is preferably 1000 cm² or more, more preferably 1500 cm² or more, further preferably 2000 cm² or more.

### (Release Layer 2)

The release layer 2 is a layer that is laminated on the first surface 1a of the support substrate 1 and is in contact with the first surface 3a of the resin substrate 3, and the composition of the release layer surface 2a is SiₓC_{y}O_{z} (0.05≤x≤0.49, 0.15≤y≤0.73, 0.22≤z≤0.36, x+y+z=1). Herein, when the value of y is less than 0.15, ash is easily generated at the time of laser beam irradiation, but when the value of y is 0.15 or more, generation of ash is suppressed and excellent releasability is obtained.

Further, when the value of y is more than 0.73, ash is easily generated at the time of laser beam irradiation, but when the value of y is 0.73 or less, generation of ash is suppressed and excellent releasability is obtained.

The release layer surface 2a of the release layer 2 refers to an outermost surface of the release layer 2 (outermost surface opposite to the support substrate 1). More specifically, when the thickness of the release layer 2 is regarded as 100%, the release layer surface 2a of the release layer 2 refers to a region of 10% distance from the outermost surface to the support substrate 1 side.

The compositions of the release layer surface 2a and other portion in the release layer 2 can be measured by X-ray photoelectron spectroscopy (XPS). Alternatively, the composition of the portion other than the release layer surface 2a may be different from or the same as the composition of the release layer surface 2a in the release layer 2.

The release layer 2 preferably contains SiₓC_{y}O_{z} (0.05≤x≤0.49, 0.15≤y≤0.73, 0.22≤z≤0.36, x+y+z=1) as a main component. Herein, the main component means that, when the whole release layer 2 is regarded as 100% by mass, the total content of SiₓC_{y}O_{z} (0.05≤x≤0.49, 0.15≤y≤0.73, 0.22≤z≤0.36, x+y+z=1) is 90% by mass or more, preferably 95% by mass or more, and more preferably 99% by mass or more.

In the release layer 2, other than SiₓC_{y}O_{z} (0.05≤x≤0.49, 0.15≤y≤0.73, 0.22≤z≤0.36, x+y+z=1) as the main component, dopant may be added.

Examples of the dopant include nitrogen (N), boron (B), aluminum (Al), and phosphorus (P), and the dopant is not limited thereto.

The content ratio of the dopant to SiₓC_{y}O_{z} (0.055≤x≤0.49, 0.15≤y≤0.73, 0.22≤z≤0.36, x+y+z=1) as the main component is preferably 10 at % or less. When the content ratio of the dopant is within the above range, favorable releasability and light absorption in an ultraviolet region can be realized.

The absorptance of the release layer 2 in the ultraviolet region may be preferably 50% or more and more preferably 60% or more. According to the definition of JIS Z8120, the lower limit wavelength of the electromagnetic wave corresponding to visible light is about 360 to 400 nm and the upper limit thereof is about 760 to 830 nm. In the present embodiment, the ultraviolet region refers to a region having a wavelength of 400 nm or less, more specifically, 10 nm or more and 400 nm or less, and the visible region refers to a region having a wavelength of more than 400 nm and 700 nm or less.

In the case of using the laser beam of the ultraviolet region (YAG laser: wavelength 355 nm) in the releasing step, when the absorptance in the wavelength region having a wavelength of 340 nm or more and 400 nm or less is 50% or more, the release layer 2 sufficiently absorbs the laser beam and the resin substrate can be properly released.

The thickness of the release layer 2 is preferably about 1 nm to 20 μm, more preferably about 10 nm to 2 μm, and further preferably about 40 nm to 1 μm. When the thickness of the release layer 2 is too thin, the uniformity of the thickness of the formed film is lost so that unevenness may possibly occur in releasing. Further, when the thickness of the release layer 2 is too thick, it is necessary to increase the energy (light intensity) of irradiation laser beam necessary for releasing.

The release layer 2 is illustrated as a single layer in FIG. 1 but can be configured by lamination of two or more layers.

Further, the release layer 2 is typically, as illustrated in FIG. 1, laminated over the entire surface of the first surface 1a of the support substrate 1, but may be laminated on a portion on the first surface 1a of the support substrate 1 as long as it has proper releasability. For example, the release layer 2 may be provided on the first surface 1a of the support substrate 1 in the form of an island or a stripe.

### (Resin Substrate 3)

In the resin substrate 3, the first surface 3a is in contact with the release layer 2 and an electronic device member P to be described later is provided on a second surface 3b that is opposite side to the release layer 2 side.

The resin constituting the resin substrate 3 may be either a thermoplastic resin or a thermosetting resin, and examples thereof include polyolefins such as polyethylene (high density, medium density, or low density), polypropylene (isotactic type or syndiotactic type), polybutene, an ethylene-propylene copolymer, an ethylene-vinyl acetate copolymer (EVA), an ethylene-propylene-butene copolymer, cyclic polyolefin, modified polyolefin, polyvinyl chloride, polyvinylidene chloride, polystyrene, polyamide, polyimide, polyamideimide, polyetherimide, aromatic polyimide such as fluorinated polyimide, polyimide-based resins such as alicyclic polyimide, polycarbonate, polyvinyl alcohol, polyethylene vinyl alcohol, poly-(4-methylpentene-1), an ionomer, an acrylic resin, polymethyl methacrylate, polybutyl(meth)acrylate, a methyl(meth)acrylate-butyl(meth)acrylate copolymer, a methyl (meth)acrylate-styrene copolymer, an acrylic-styrene copolymer (AS resin), a butadiene-styrene copolymer, an ethylene vinyl alcohol copolymer (EVOH), polyesters such as polyethylene terephthalate (PET), polybutylene terephthalate (PBT), ethylene-terephthalate-isophthalate copolymer, polyethylene naphthalate, and precyclohexane terephthalate (PCT), polyether, polyether ketone (PEK), polyether ether ketone (PEEK), polyetherimide, polyacetal (POM), polyphenylene oxide, modified polyphenylene oxide, polyarylate, aromatic polyester, polytetrafluoroethylene (PTFE), polyvinylidene fluoride, other fluorine resins, various thermoplastic elastomers such as styrene based, polyolefin based, polyvinyl chloride based, polyurethane based, fluorine rubber based, and chlorinated polyethylene based, an epoxy resin, phenolic resin, urea resin, melamine resin, unsaturated polyester, silicone resin, polyurethane, nylon, cellulose-based resins such as nitrocellulose, cellulose acetate, and cellulose acetate propionate, and a copolymer, a blend, and a polymer alloy mainly composed thereof. These can be used singly or in combination of two or more kinds thereof (for example, as a laminate of two or more layers).

The resin substrate 3 is preferably a film using a polymer having a heat resistance of 100° C. or higher, that is, a film using so-called engineering plastic. The film using engineering plastic is, for example, preferably an aromatic polyester film, and examples thereof further include super engineering plastic films such as an aromatic polyamide film, a polyamideimide film, and a polyimide film which have a heatproof temperature of higher than 150° C. The heat resistance described herein refers to a glass transition temperature or a heat distortion temperature.

The thickness of the resin substrate 3 is not particularly limited, but the thickness of the polymer film is preferably 3 μm or more, more preferably 11 μm or more, further preferably 24 μm or more, and still more preferably 45 μm or more. The upper limit of the thickness of the polymer film is not particularly limited, but from the viewpoint of a decrease in thickness of a final electronic device and flexibilization, the thickness is preferably 250 μm or less, more preferably 150 m or less, and further preferably 90 m or less. Alternatively, a laminate obtained by laminating two or more resin layers may be used as the resin substrate 3.

### (Use Application of Resin Substrate Laminate S)

As described above, the resin substrate laminate S of the present embodiment is a laminate obtained by releasably laminating the release layer-attached support substrate 4 and the resin substrate 3 while using the release layer surface 2a of the release layer-attached support substrate 4 and the first surface 3a of the resin substrate 3 mentioned above as lamination surfaces. That is, the resin substrate laminate S is a laminate including the release layer 2 interposed between the support substrate 1 and the resin substrate 3.

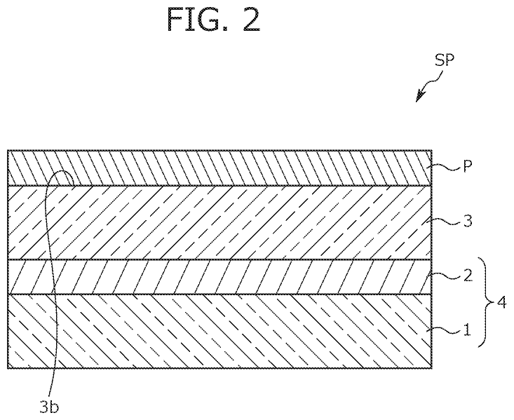

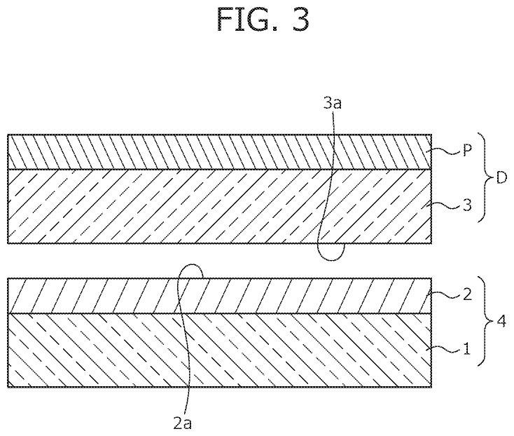

The resin substrate laminate S having such a configuration is used in manufacturing of an electronic device, as described later. Specifically, as illustrated in FIG. 2, in the resin substrate laminate S, the electronic device member P is formed on the surface of the second surface 3b. Thereafter, as illustrated in FIG. 3, the release layer-attached support substrate 4 is released at the interface with the resin substrate 3 and the release layer-attached support substrate 4 is not a member constituting an electronic device. In the release layer-attached support substrate 4 from which the resin substrate 3 having the electronic device member P formed thereon is separated, a new resin substrate 3 is laminated and the resultant laminate can be reused as the release layer-attached support substrate 4.

The resin substrate laminate S of the present invention can be used in various uses, and for example, uses in the manufacturing of an electronic device such as a panel for a display device, such as a liquid crystal panel (LCD), an organic EL display (OLED), electronic paper, a field emission panel, a quantum dot LED panel, or a MEMS shutter panel, a photovoltaic cell (PV), a thin film secondary battery, and a semiconductor wafer having a circuit formed on the surface thereof are exemplified.

### <Method for Manufacturing Electronic Device D>

The method for manufacturing an electronic device of the present embodiment performs a step of preparing a resin substrate laminate by laminating a release layer on a support substrate using a target having a ratio of Si:C of 10:90 to 90:10 and laminating a resin substrate on a surface, which is opposite to the support substrate, of the release layer, a member forming step of forming an electronic device member on a surface of the resin substrate of the resin substrate laminate, and a releasing step of releasing the resin substrate from the release layer by irradiating the release layer with a laser beam.

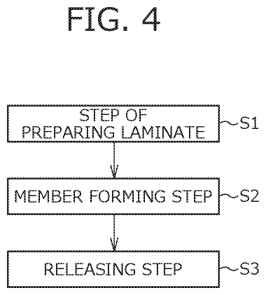

Hereinafter, respective steps will be described in detail with reference to FIG. 4.

### (Step of Preparing Resin Substrate Laminate)

In the step of preparing a resin substrate laminate (Step S1), first, the release layer 2 is laminated on the support substrate 1 to obtain the release layer-attached support substrate 4 and the resin substrate 3 is laminated on the release layer-attached support substrate 4.

Specifically, the release layer 2 is laminated on the support substrate 1 using a target having a ratio of Si:C of 10:90 to 90:10 to obtain the release layer-attached support substrate 4 and the resin substrate 3 is laminated on the surface 2a, which is opposite to the support substrate 1, of the release layer 2 in the release layer-attached support substrate 4.

The method for forming the release layer 2 on the support substrate 1 in the release layer-attached support substrate 4 may be a method in which a release layer can be formed to have an uniform thickness and can be appropriately selected according to various conditions such as the composition, thickness, and the like of the release layer 2. For example, the method can be applied to various vapor phase deposition methods such as a CVD (including MOCCVD, low-pressure CVD, and ECR-CVD) method, vapor deposition, molecular-beam deposition (MB), a sputtering method, an ion plating method, and a PVD method, application methods such as Langmuir-Blodgett (LB) method, spin coating, a spray coating method, and a roll coating method, various printing methods, a transfer method, an inkjet method, a powder jet method, and the like. Of these, two or more kinds of the methods may be combined.

For example, a SiC target is used, a mixed gas of inert gas of Ar or the like and oxygen atom-containing gas of O₂ or the like is introduced, and the release layer 2 is provided on the first surface 1a of the support substrate 1 by a vapor deposition method, a sputtering method, a CVD method, or the like, thereby manufacturing the release layer-attached support substrate 4. At this time, by adjusting the composition of the target or the amount of the oxygen atom-containing gas in the mixed gas, the oxygen amount (value of z) of the release layer surface 2a of the release layer 2 can be controlled. Alternatively, the film forming conditions for the release layer 2 may be appropriately selected according to a material to be used or the like.

As the target used when the release layer 2 is formed, materials such as silicon carbide (SiC), silicon carbon oxide (SiCO), silicon oxide (SiO₂), and silicon (Si) can be used singly or in combination such that the ratio of Si:C is 10:90 to 90:10. At this time, by adjusting the ratio of Si:C of the target, the silicon amount (value of x) and the carbon amount (value of y) of the release layer surface 2a of the release layer 2 can be controlled.

The ratio of Si:C in the target used when the release layer 2 is formed may be Si:C=10:90 to 90:10, and is more preferably Si:C=10:90 to 30:70 and particularly preferably Si:C=10:90 to 50:50.

The method for laminating the resin substrate 3 on the release layer 2 of the release layer-attached support substrate 4 in the resin substrate laminate S is not particularly limited, and a method of applying and drying a solution of a resin constituting the resin substrate 3 or a solution of a resin precursor to form a film can be used.

The application of the solution of the resin or the solution of the resin precursor onto the release layer 2 can be carried out, for example, by appropriately using a known solution applying means such as spin coating, doctor blade, applicator, comma coater, screen printing method, slit coating, reverse coating, dip coating, curtain coating, or slit die coating.

For example, in a case where the resin substrate 3 is a polyimide-based resin film, the polyimide-based resin film can be obtained by applying a polyamide acid (polyimide precursor) solution obtained by reaction of diamines and tetracarboxylic acids in a solvent onto the release layer 2 to have a predetermined thickness, drying the applied solution, and then performing a heat imidization method in which dehydration ring-closing reaction is performed by high temperature heat treatment or a chemical imidization method using acetic anhydride or the like as a dehydrating agent and pyridine or the like as a catalyst.

Further, in a case where the resin substrate 3 is a thermoplastic resin film, the thermoplastic resin film can be obtained by a melt drawing method. In addition, in a case where the resin substrate 3 is not a thermoplastic resin, a resin film can be obtained by a solution film forming method.

Further, depending on the type of resin, a method of physically laminating a resin film on the release layer 2 can also be used. For example, there are exemplified a method of superimposing the release layer-attached support substrate 4 and the resin substrate 3 under normal pressure environment, then lightly pressing one spot of the second surface 3b of the resin substrate 3 to generate a close adhesion starting point in the superimposed plane, and naturally widening the close adhesion from the close adhesion starting point, a method of widening the close adhesion from the close adhesion starting point by press-bonding using rolls or a press, and the like. In the case of press-bonding using rolls or a press, the release layer surface 2a of the release layer 2 and the first surface 3a of the resin substrate 3 are in closer contact with each other and air bubbles incorporated between the both surfaces are relatively easily removed, which is preferable.

Further, when the release layer 2 and the resin substrate 3 are press-bonded by a vacuum lamination method or a vacuum press method, suppression of incorporation of air bubbles and securement of good close adhesion are preferably performed, which is more preferable. There is an advantage that by press-bonding under vacuum, even in a case where fine air bubbles remain, air bubbles do not grow by heating and this is difficult to lead to distortion and defects.

It is preferable that when the release layer-attached support substrate 4 is releasably and closely adhered to the resin substrate 3, surfaces at contacting sides of the release layer 2 and the resin substrate 3 are sufficiently cleaned, and those are laminated in an environment having high cleanliness. The cleaning method is not particularly limited, but for example, a method in which the surface of the release layer 2 or the resin substrate 3 is cleaned with an alkali aqueous solution, and then further cleaned using water is exemplified.

Further, in order to obtain a favorable lamination state, it is preferable to subject surfaces at contacting sides of the release layer 2 and the resin substrate 3 to a plasma treatment after cleaning and then laminate those layers. Examples of plasma used in the plasma treatment include atmospheric plasma, vacuum plasma, and the like.

### (Member Forming Step)

In the member forming step (Step S2), an electronic device member is formed on a surface of the resin substrate of the resin substrate laminate.

Specifically, as illustrated in FIG. 2, in this step, the electronic device member P is formed on the second surface 3b of the resin substrate 3 to manufacture an electronic device member-attached laminate SP.

First, the electronic device member P used in this step will be described and then this step will be described in detail.

The electronic device member P is a member that constitutes at least a portion of an electronic device D formed on the second surface 3b of the resin substrate 3 of the resin substrate laminate S. Specifically, examples of the electronic device member P include members used in electronic components such as a panel for a display device such as OLED, a photovoltaic cell, a thin film secondary battery, and a semiconductor wafer having a circuit formed on the surface thereof.

Examples of the member for OLED may include a TFT element formed by laminating an electrode and an organic layer and etching the laminate, a drive circuit, and the like.

Further, examples of the member for a photovoltaic cell include a transparent electrode such as zinc oxide of a positive electrode, a silicon layer represented by p layer/i layer/n layer, and a metal of a negative electrode, in a silicon type. Other than, examples thereof may include various members corresponding to a compound type, a dye sensitization type, a quantum dot type, and the like.

Further, examples of the member for a thin film secondary battery include a transparent electrode of a metal or a metal oxide of a positive electrode and a negative electrode, a lithium compound of an electrolyte layer, a metal of a current collection layer, and a resin as a sealing layer, in a lithium ion type. Other than, examples thereof may include various members corresponding to a nickel hydrogen type, a polymer type, ceramics electrolyte type, and the like.

Further, examples of the member for an electronic component include a metal of a conductive portion, and silicon oxide and silicon nitride of an insulating portion, in CCD and CMOS. Other than, examples thereof may include various sensors such as a pressure sensor and an acceleration sensor, and various members corresponding to a rigid printed circuit board, a flexible printed circuit board, a rigid flexible printed circuit board, and the like.

The method for manufacturing the electronic device member-attached laminate SP is not particularly limited, and the electronic device member P is formed on the second surface 3b of the resin substrate 3 of the resin substrate laminate S using a known method according to the kind of a constructional member of the electronic device member P.

Alternatively, the electronic device member P may not be the whole of the member finally formed on the surface of the second surface 3b of the resin substrate 3 but may be a portion of the member. A partial member-attached resin substrate can be formed into a whole member-attached resin substrate (corresponding to an electronic device to be described later) by the subsequent steps. Further, in the resin substrate, other electronic device member may be formed on the release surface (first surface 3a) thereof. Furthermore, the electronic device D can also be manufactured by fabricating a whole member-attached laminate and then releasing the release layer-attached support substrate 4 from the resin substrate 3 on which the electronic device member P is formed.

For example, in the case of manufacturing OLED, in order to form an organic EL structure on the surface of the second surface 3b of the resin substrate 3 of the resin substrate laminate S, various layer formations and treatments, such as forming a transparent electrode, further depositing a hole injection layer, a hole transport layer, a light emission layer, an electron transport layer and the like on the surface having the transparent electrode formed thereon, forming a back electrode, and sealing using a sealing plate, are conducted. Examples of those layer formations and treatments specifically include a film forming treatment, a deposition treatment and an adhesion treatment of a sealing plate.

Further, for example, a method for manufacturing TFT-LCD includes various steps such as a TFT forming step of forming a thin film transistor (TFT) on the surface of the second surface 3b of the resin substrate 3 of the resin substrate laminate S using a resist liquid by conducting pattern formation on a metal film, a metal oxide film, and the like formed by a general film forming method such as a CVD method or a sputtering method, a CF forming step of forming a color filter (CF) on the second surface 3b of the resin substrate 3 of another resin substrate laminate S by using a resist liquid in pattern formation, and a bonding step of laminating a TFT-attached device substrate and a CF-attached device substrate.

In the TFT forming step and the CF forming step, TFT and CF are formed on the second surface 3b of the resin substrate 3 using a known photolithography technology, etching technology, or the like. At this time, a resist liquid is used as a coating liquid for pattern formation. Alternatively, prior to the formation of TFT and CF, the second surface 3b of the resin substrate 3 may be cleaned as necessary. As the cleaning method, a known dry cleaning or wet cleaning can be used. In the bonding step, a liquid crystal material is injected between the TFT-attached laminate and the CF-attached laminate, and lamination is then conducted. Examples of a method for injecting a liquid crystal material include a vacuum injection method and a dropping injection method.

### (Releasing Step)

In the releasing step (Step S3), the resin substrate is released from the release layer by irradiating the release layer of the electronic device member-attached laminate obtained in the member forming step with a laser beam to obtain the electronic device D including the electronic device member P and the resin substrate 3. That is, the releasing step is a step of separating the electronic device member-attached laminate SP into the release layer-attached support substrate 4 and the electronic device D.

In a case where the electronic device member P on the resin substrate 3 after releasing is a portion of the final whole constructional member, the remaining constructional member may be formed on the resin substrate 3 after releasing.

When the release layer surface 2a of the release layer 2 and the first surface 3a of the resin substrate 3 are released (separated), a laser beam is irradiated to the release layer 2 from the rear surface side of the support substrate 1, that is, the second surface 1b side.

As the laser beam, a laser beam which causes the interfaces of the release layer 2 and the resin substrate 3 to be released may be used, and pulse oscillation type or continuous emission type excimer laser, YAG laser, or YVO₄ laser can be used. Since the excimer laser outputs high energy in a short wavelength region, the excimer laser can cause ablation on the release layer in a very short time.

The energy density of the laser beam is set to preferably about 10 to 100 mJ/cm², and particularly, more preferably about 60 to 80 mJ/cm².

The irradiation time of the laser beam is set to preferably about 1 to 5000 nanoseconds, more preferably about 1 to 3000 nanoseconds, further preferably about 1 to 1000 nanoseconds, and particularly preferably about 10 to 100 nanoseconds.

In a case where the energy density of the laser beam is low or the irradiation time is short, releasing is not sufficient. Further, in a case where the energy density of the laser beam is high or the irradiation time is long, irradiation light passing through the release layer 2 may cause adverse effects on the resin substrate 3 or the electronic device member P.

In the case of using a glass substrate as the support substrate 1, fundamental (wavelength 1064 nm), the second harmonic (wavelength 532 nm), and the third harmonic (wavelength 355 nm) of YAG laser are preferably used. Since a material constituting the release layer 2 includes SiₓC_{y}O_{z}(0.05≤x≤0.49, 0.15≤y≤0.73, 0.22≤z≤0.36, x+y+z=1) as a main component and has an absorption band in an ultraviolet region, the third harmonic (wavelength 355 nm) may be used and caused to pass through the support substrate 1 to irradiate the release layer 2.

Preferably, the electronic device member-attached laminate SP is placed on a surface plate such that the support substrate 1 is an upper side and the electronic device member P side is a lower side, the electronic device member P side is vacuum sucked on the surface plate, and in this state, the laser beam is irradiated to the release layer 2 from the support substrate 1 side. Thereafter, the support substrate 1 side is sucked by a plurality of vacuum suction pads, and the vacuum suction pads are sequentially raised. As a result, the electronic device D can be released from the release layer-attached support substrate 4 in the interface between the release layer 2 and the resin substrate 3.

The electronic device D obtained by the above steps is suitable for manufacturing a small-sized display device to be used in a mobile terminal such as a mobile phone, a smartphone, a PDA, or a tablet PC. The display device is mainly LCD or OLED, and the LCD includes TN type, STN type, FE type, TFT type, MIM type, IPS type, VA type, and the like. Basically, it can also be applied to the case of any of display devices of passive drive type and active drive type.

In the present embodiment, the resin substrate laminate and the method for manufacturing an electronic device using the resin substrate laminate according to the present invention have been mainly described.

However, the above embodiment is merely an example to facilitate understanding of the present invention, and the present invention is not limited thereto. The present invention can be changed and improved without departing from the gist thereof, and as a matter of course, the present invention includes equivalents thereof.

### EXAMPLE

Hereinafter, the resin substrate laminate and the method for manufacturing an electronic device using the resin substrate laminate of the present invention will be described in detail by means of specific Examples; however, the present invention is not limited thereto.

<A. Formation of Resin Substrate Laminate according to Examples and Comparative Examples>

### (A-1. Release Layer Forming Step)

Under the following conditions, a release layer according to each of Examples and Comparative Examples was laminated on a glass plate (length 100 mm, width 100 mm, plate thickness 0.7 mm, trade name “NA32SG” manufactured by AvanStrate Inc.) as a support substrate to prepare a release layer-attached support substrate. A four-layer batch-type cleaning of one neutral detergent layer, two pure water layers, and a pure water pull-up layer was executed to the release layer-attached support substrate.

### Comparative Example 1-1 (GC: Glassy Carbon)

Sputtering device: Carousel batch-type sputtering device

Target: Glassy carbon (GC), thickness 6.35 mm

Sputtering method: DC pulse application, magnetron sputtering

Exhaust device: Turbo-molecular pump

Ultimate degree of vacuum: 1.0×10⁻⁴ Pa (7.5×10⁻⁶ Torr)

Substrate temperature: 200° C.

Sputtering power: 2.5 kW/cm²

Film thickness: 100±10 nm

Ar flow rate: 330 sccm

### Comparative Example 1-2 (DLC: Diamond-Like Carbon)

Sputtering device: Carousel batch-type sputtering device

Target: Carbon (C), thickness 6.35 mm

Sputtering method: DC pulse application, magnetron sputtering

Exhaust device: Turbo-molecular pump

Ultimate degree of vacuum: 1.0×10⁻⁴ Pa (7.5×10⁻⁶ Torr)

Substrate temperature: 200° C.

Sputtering power: 2.5 kW/cm²

Film thickness: 100±10 nm

Ar flow rate: 330 sccm

### Comparative Example 1-3 (TiO₂)

Sputtering device: Carousel batch-type sputtering device

Target: Titanium (Ti), thickness 6.35 mm

Sputtering method: DC magnetron sputtering

Exhaust device: Turbo-molecular pump

Ultimate degree of vacuum: 1.0×10⁻⁴ Pa (7.5×10⁻⁶ Torr)

Substrate temperature: 200° C.

Sputtering power: 2.5 kW/cm²

Film thickness: 100±10 nm

Ar flow rate: 240 sccm

O₂ flow rate: 60 sccm

### Example 1

Sputtering device: Carousel batch-type sputtering device

Target: Silicon carbide (SC), thickness 6.35 mm

Sputtering method: DC pulse application, magnetron sputtering

Exhaust device: Turbo-molecular pump

Ultimate degree of vacuum: 1.0×10⁻⁴ Pa (7.5×10⁻⁶ Torr)

Substrate temperature: 25° C. (room temperature), 200° C.

Sputtering power: 2.5 kW/cm²

Film thickness: 100±10 nm

Ar flow rate: 330 sccm

### Examples 2-1 to 2-5 (SiC)

Sputtering device: Carousel batch-type sputtering device

Target: SiC target, thickness 6.35 mm
Si: 23.5 wt %, SiC: 53.9 wt %, C 22.9 wt %

Sputtering method: DC pulse application, magnetron sputtering

Exhaust device: Turbo-molecular pump

Ultimate degree of vacuum: 1.0×10⁻⁴ Pa (7.5×10⁻⁶ Torr)

Substrate temperature: 25° C. (room temperature), 200° C.

Sputtering power: 2.5 kW/cm²

Film thickness: 100±10 nm

Ar flow rate: 330 sccm

### Example 3-1 (Si: Silicon)

Sputtering device: Carousel batch-type sputtering device

Target: Silicon (Si), thickness 6.35 mm

Sputtering method: DC pulse application, magnetron sputtering

Exhaust device: Turbo-molecular pump

Ultimate degree of vacuum: 1.0×10⁻⁴ Pa (7.5×10⁻⁶ Torr)

Substrate temperature: 200° C.

Sputtering power: 2.5 kW/cm²

Film thickness: 100±10 nm

Ar flow rate: 330 sccm

### Examples 3-2 to 3-6 (SiC: Silicon Carbide)

Sputtering device: Carousel batch-type sputtering device

Target: Mixing silicon (Si) and carbon (C) at a predetermined ratio, thickness 6.35 mm

Sputtering method: DC pulse application, magnetron sputtering

Exhaust device: Turbo-molecular pump

Ultimate degree of vacuum: 1.0×10⁻⁴ Pa (7.5×10⁻⁶ Torr)

Substrate temperature: 200° C.

Sputtering power: 0.6 to 2.5 kW/cm² (setting a value according to a ratio of Si and C)

Film thickness: 100±10 nm

Ar flow rate: 330 sccm

### Example 3-7 (C: Carbon)

Sputtering device: Carousel batch-type sputtering device

Target: Carbon (C), thickness 6.35 mm

Sputtering method: DC pulse application, magnetron sputtering

Exhaust device: Turbo-molecular pump

Ultimate degree of vacuum: 1.0×10⁻⁴ Pa (7.5×10⁻⁶ Torr)

Substrate temperature: 200° C.

Sputtering power: 2.5 kW/cm²

Film thickness: 100±10 nm

Ar flow rate: 330 sccm

### (A-2. Resin Substrate Laminating Step)

As described later, a polyimide resin substrate (resin substrate) was laminated. A solvent dilution solution of a polyimide resin forming material (Pyralin (registered trademark) PI2610 manufactured by Hitachi Chemical DuPont MicroSystems L.L.C.) was applied onto the release layer of the release layer-attached support substrate (target film thickness 10 μm) using a spin coater (K359S1 manufactured by Kyowa Riken Co., Ltd.) under predetermined spinner conditions (initial speed 600 rpm-20 seconds, second speed 3500 rpm-0.7 seconds). Leveling (placing in flat orientation) for uniformization of the substrate surface after application was performed for 1 minute. Prebaking was performed using a hot plate under the conditions of 130° C.-5 minutes. Then, postbaking was performed using an oven under the conditions of 300° C.-90 minutes, and the polyimide resin substrate (length 100 mm, width 100 mm, thickness 8.4 μm) was laminated, thereby obtaining a resin substrate laminate.

### <B. Release Test (LLO: Laser Lift-Off Test)>

The resin substrate was released from the release layer by irradiating the release layer of the resin substrate laminate with a laser beam from the glass substrate side. Herein, the laser beam irradiation was performed using YAG solid laser (wavelength: 355 nm) by scanning with a spot diameter of 25.4 μm (60% of the abscissa axis being overlapped) for an irradiation time of 30 minutes.

After the laser beam irradiation, cuts were made by a sharp cutter in four sides at a distance of 2 mm from the outer circumference of a 100×100 mm resin substrate laminate, one place of four corners was anchored with tweezers, the resin substrate (polyimide substrate) was slowly peeled from the release layer at a constant speed, and thus sensory assessment of adhesion between the release layer and the resin substrate was performed.

The releasability was evaluated as follows.

⊙: The resin substrate is released without any resistance.

◯: The resin substrate is released although there is slight resistance.

Δ: The resin substrate is released although there is resistance.

X: The resin substrate is not released or is torn.

The change in color (Yes/Not) of the release layer was evaluated as followed.

The existence of the change in color was determined from an optical microscope image (×500).

As the result of XRD analysis, a peak showing a crystalline structure was detected at a faint color place (only yellow).

The existence of ashes (ashes: ashes or soot fine particles caused by heat generation by laser irradiation) was determined by the existence of transfer to a cloth wiper side when the release layer was rubbed with the wiper.

### <Test 1: Investigation of Materials Used in Release Layer>

In Test 1, materials used in the release layer were investigated.

As shown in Table 1, a release layer-attached support substrate having various release layers (film thickness 100 nm) laminated on a glass substrate (thickness: 0.7 mm) as the support substrate was used, and a polyimide substrate (thickness: 8.4 μm) as the resin substrate was laminated on the surface, which is opposite to the glass substrate, of the release layer, thereby manufacturing a resin substrate laminate.

TABLE 1

| | Film configuration | LLO |
|---|---|---|
| | Support substrate/Release layer/Resin | condition |
| Sample | substrate | (mJ/cm²) |
| Comparative | Glass/Glassy carbon (GC)/Polyimide | 80 |
| Example 1-1 | | |
| Comparative | Glass/Diamond-like carbon | 80 |
| Example 1-2 | (DLC)/Polyimide | |
| Comparative | Glass/TiO₂/Polyimide | 80 |
| Example 1-3 | | |
| Example 1 | Glass/SiC/Polyimide | 80 |

Light irradiation was performed to each resin substrate laminate using YAG solid laser (wavelength: 355 nm) by scanning with a spot diameter of 25.4 μm for an irradiation time of 30 minutes at a laser intensity of 80 mJ/cm², and releasability and ashes of the polyimide substrate after laser beam irradiation were investigated.

The results are shown in Table 2.

TABLE 2

| | | 80 mJ/cm² | |
|---|---|---|---|
| Sample | Release layer | Releasability | Ash |
| Comparative | Glassy carbon (GC) | Δ | — |
| Example 1-1 | | | |
| Comparative | Diamond-like carbon (DLC) | Δ | — |
| Example 1-2 | | | |
| Comparative | TiO₂ | X | Yes |
| Example 1-3 | | | |
| Example 1 | SiC | ◯ | No |

It was found that in the case of using SiC as the release layer, the polyimide substrate can be released without SiC as the release layer being released from the glass substrate.

Further, it was found that in the case of using glassy carbon (GC) or diamond-like carbon (DLC) as the release layer, the release layer as well as the polyimide substrate is released.

Further, it was found that in the case of using TiO₂ as the release layer, the polyimide substrate and the release layer stick to each other.

### <Test 2: Investigation of Laser Beam Intensity>

In Table 2, the laser beam intensity in the releasing step was investigated.

As shown in Table 3, a glass substrate (thickness: 0.7 mm) and a polyimide substrate (thickness: 8.4 μm) were used respectively as the support substrate and the resin substrate to prepare a sample having a SiC release layer and a sample not having a SiC release layer.

TABLE 3

| | Film configuration | Laser |
|---|---|---|
| | Support substrate/Release layer/Resin | intensity |
| Sample | substrate | (mJ/cm²) |
| Example 2-1 | Glass/SiC/Polyimide | 100 |
| Example 2-2 | Glass/SiC/Polyimide | 90 |
| Example 2-3 | Glass/SiC/Polyimide | 80 |
| Example 2-4 | Glass/SiC/Polyimide | 70 |
| Example 2-5 | Glass/SiC/Polyimide | 60 |
| Comparative | Glass/None/Polyimide | 110 |
| Example 2-1 | | |
| Comparative | Glass/None/Polyimide | 105 |
| Example 2-2 | | |
| Comparative | Glass/None/Polyimide | 100 |
| Example 2-3 | | |
| Comparative | Glass/None/Polyimide | 95 |
| Example 2-4 | | |
| Comparative | Glass/None/Polyimide | 90 |
| Example 2-5 | | |

Light irradiation was performed to each sample using YAG solid laser (wavelength: 355 nm) by scanning with a spot diameter of 25.4 m for an irradiation time of 30 minutes, and releasability and ashes of the polyimide substrate after laser beam irradiation were investigated.

Specifically, the laser beam intensity was optimized in the polyimide substrate directly on the glass substrate, and then the laser beam intensity was lowered from the optimum value every 10% until the release layer could not be released. The results are shown in Table 4 and Table 5.

TABLE 4

| | | Laser | | |
|---|---|---|---|---|
| | Release | intensity | | |
| Sample | layer | (mJ/cm²) | Releasability | Ash |
| Example 2-1 | SiC | 100 | ◯ | No |
| Example 2-2 | SiC | 90 | ◯ | No |
| Example 2-3 | SiC | 80 | ◯ | No |
| Example 2-4 | SiC | 70 | ◯ | No |
| Example 2-5 | SiC | 60 | ◯ | No |

TABLE 5

| | | Laser | | |
|---|---|---|---|---|
| | Release | intensity | | |
| Sample | layer | (mJ/cm²) | Releasability | Ash |
| Comparative | None | 110 | ◯ | Yes |
| Example 2-1 | | | | |
| Comparative | None | 105 | ◯ | Yes |
| Example 2-2 | | | | |
| Comparative | None | 100 | ◯ | Yes |
| Example 2-3 | | | | |
| Comparative | None | 98 | ◯ | Yes |
| Example 2-4 | | | | |
| Comparative | None | 90 | ◯ | Yes |
| Example 2-5 | | | | |

By irradiating the samples of Examples with a laser beam at 60 to 100 mJ/cm², the polyimide substrate was released without resistance and ashes were also not generated. In the samples of Comparative Examples, although the releasability of the polyimide substrate was favorable, adhesion between the polyimide substrate and the glass substrate was not secured.

The composition analysis of each glass substrate/SiC film sample by X-ray photoelectron spectroscopy (XPS: JPS-90000MC manufactured by JEOL Ltd.) was performed before and after laser beam irradiation.

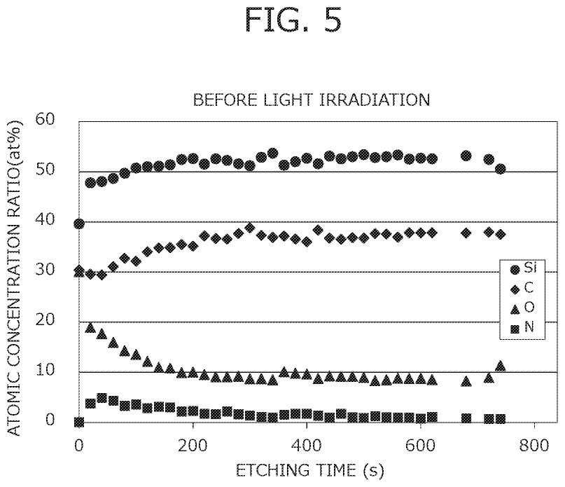

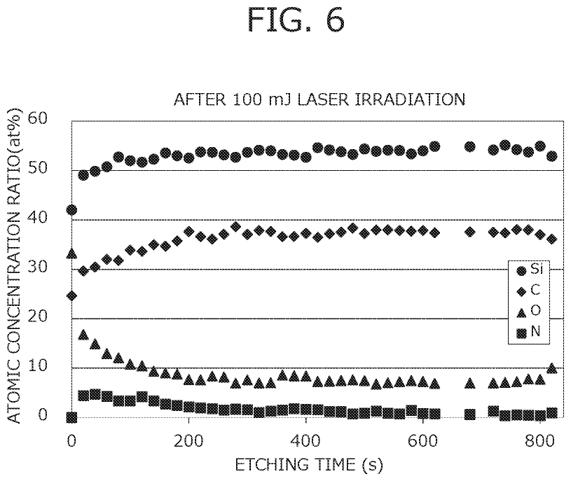

The results are shown in FIG. 5 (before laser beam irradiation) and FIG. 6 (after laser beam irradiation at 100 mJ/cm²).

It was found that before and after laser beam irradiation, the composition in the sample surface of the glass substrate/SiC film does not change, and the release layer is stable to laser beam irradiation.

### <Test 3: Investigation of Reuse of Release Layer-Attached Support Substrate>

In Table 3, the samples in which the releasing of the polyimide substrate was performed by laser irradiation in Test 2 shown in Table 6 were released again under the same conditions by laser irradiation, and thus investigation whether the release layer-attached support substrate is reusable was conducted.

After the polyimide substrate was released in Test 2, the polyimide substrate was laminated again. Laser irradiation was performed at the same intensity as the intensity of the laser beam irradiated in Test 2. The results are shown in Table 7.

TABLE 6

| | Film configuration | |
|---|---|---|
| | Support substrate/Release | Laser intensity |
| Sample | layer/Resin substrate | (mJ/cm²) |
| Example 2-2 | Glass/SiC/Polyimide | 90 |
| Example 2-3 | Glass/SiC/Polyimide | 80 |
| Example 2-4 | Glass/SiC/Polyimide | 70 |

TABLE 7

| | Laser | | | |
|---|---|---|---|---|
| | intensity | Release layer | | |
| Sample | (mJ/cm²) | (reuse) | Releasability | Ash |
| Example 2-2 | 90 | SiC | ◯ | No |
| Example 2-3 | 80 | SiC | ◯ | No |
| Example 2-4 | 70 | SiC | ◯ | No |

Similarly to Test 2, even in the case of reuse, the sticking force of the polyimide substrate on the release layer was secured. It was possible to easily release the polyimide substrate by a laser beam at 70 to 90 mJ/cm². In any of laser intensities, generation of ashes was not found. From the above description, it was found that the release layer-attached support substrate according to the present embodiment can be repeatedly used (reused).

### <Test 4: Investigation of Composition of Release Layer>

In Test 4, an influence of the composition ratio of Si and C on the releasability was investigated by changing the composition ratio of Si and C contained in the release layer.

### (1. Preparation of Sample)

Samples shown in Table 8 were prepared by performing binary sputtering film formation.

TABLE 8

| | Film configuration |
|---|---|
| Sample | Support substrate/Release layer/Resin substrate |
| Reference | Glass/Si(100)—C(0)/Polyimide |
| Example 3-1 | |
| Example 3-1 | Glass/Si(90)—C(10)/Polyimide |
| Example 3-2 | Glass/Si(70)—C(30)/Polyimide |
| Example 3-3 | Glass/Si(50)—C(50)/Polyimide |
| Example 3-4 | Glass/Si(30)—C(70)/Polyimide |
| Example 3-5 | Glass/Si(10)—C(90)/Polyimide |
| Reference | Glass/Si(0)—C(100)/Polyimide |
| Example 3-2 | |

### (2. Composition Analysis by XPS)

The composition analysis of each sample by XPS (device: JPS-90000MC manufactured by JEOL Ltd.) was performed under the following conditions.

Analysis Conditions

X-ray source: MgKα

X-ray output: 10 kV×10 mA (100 W)

EPass: 10 eV

Step: 0.1 eV

Dwell time×cumulated number: 100 mS×8

Measurement element: C, N, O, Si

The results are shown in Table 9 and Table 10.

Table 9 shows the atomic concentrations of carbon (C), nitrogen (N), oxygen (O), and silicon (Si) of each sample in surface, etching 40 seconds (etch: 40 s, etching depth about 20 nm), and etching 80 seconds (etch: 80 s, etching depth about 40 nm).

Table 10 shows the ratios of carbon (C), oxygen (O), and silicon (Si) of each sample in surface, etching 40 seconds (etch: 40 s, etching depth about 20 nm), etching 80 seconds (etch: 80 s, etching depth about 40 nm).

TABLE 9

| Determination | | Atomic concentration ratio (at %) | | | | | | |
|---|---|---|---|---|---|---|---|---|
| result | | Reference | | | | | | Reference |
| (surface) | | Example | Example | Example | Example | Example | Example | Example |
| Element | State | 3-2 | 3-5 | 3-4 | 3-3 | 3-2 | 3-1 | 3-1 |
| C | 1s | 80.2 | 72.9 | 56.8 | 42.7 | 27.3 | 14.9 | 10.3 |
| N | 1s | — | 0.5 | — | — | 0.6 | 0.7 | — |
| O | 1s | 19.8 | 21.6 | 23.2 | 22.6 | 29.7 | 35.8 | 37.5 |
| Si | 2p3/2 | 0.1 | 5.0 | 20.0 | 34.6 | 43.0 | 48.5 | 52.2 |
| Determination | | Atomic concentration ratio (at %) | | | | | | |
| result | | Reference | | | | | | Reference |
| (etch: 40 s) | | Example | Example | Example | Example | Example | Example | Example |
| Element | State | 3-2 | 3-5 | 3-4 | 3-3 | 3-2 | 3-1 | 3-1 |
| C | 1s | 96.1 | 85.5 | 62.7 | 44.9 | 31.4 | 10.9 | 5.9 |
| N | 1s | 1.4 | 0.6 | 0.8 | 1.6 | 1.3 | 0.7 | 1.6 |
| O | 1s | 2.6 | 6.7 | 9.7 | 11.7 | 8.5 | 9.0 | 14.7 |
| Si | 2p3/2 | — | 7.9 | 26.8 | 41.8 | 58.8 | 79.4 | 77.8 |
| Determination | | Atomic concentration ratio (at %) | | | | | | |
| result | | Reference | | | | | | Reference |
| (etch: 80 s) | | Example | Example | Example | Example | Example | Example | Example |
| Element | State | 3-2 | 3-5 | 3-4 | 3-3 | 3-2 | 3-1 | 3-1 |
| C | 1s | 96.9 | 84.3 | 63.8 | 46.0 | 31.7 | 14.1 | 4.8 |
| N | 1s | 1.1 | 0.7 | 1.1 | 0.9 | 2.2 | 0.8 | 1.1 |
| O | 1s | 2.0 | 7.4 | 8.8 | 10.1 | 7.1 | 7.6 | 12.0 |
| Si | 2p3/2 | — | 7.6 | 26.3 | 43.0 | 59.0 | 77.5 | 82.1 |

TABLE 10

| | | Atomic concentration ratio C:O:Si | | | | | | |
|---|---|---|---|---|---|---|---|---|
| | | Reference | | | | | | Reference |
| (surface) | | Example | Example | Example | Example | Example | Example | Example |
| Element | State | 3-2 | 3-5 | 3-4 | 3-3 | 3-2 | 3-1 | 3-1 |
| C | 1s | 0.80 | 0.73 | 0.57 | 0.43 | 0.27 | 0.15 | 0.10 |
| O | 1s | 0.20 | 0.22 | 0.23 | 0.23 | 0.30 | 0.36 | 0.38 |
| Si | 2p3/2 | 0.00 | 0.05 | 0.20 | 0.34 | 0.43 | 0.49 | 0.52 |
| | | Atomic concentration ratio C:O:Si | | | | | | |
| | | Reference | | | | | | Reference |
| (etch: 40 s) | | Example | Example | Example | Example | Example | Example | Example |
| Element | State | 3-2 | 3-5 | 3-4 | 3-3 | 3-2 | 3-1 | 3-1 |
| C | 1s | 0.97 | 0.85 | 0.63 | 0.46 | 0.31 | 0.11 | 0.06 |
| O | 1s | 0.03 | 0.07 | 0.10 | 0.12 | 0.09 | 0.09 | 0.15 |
| Si | 2p3/2 | 0.00 | 0.08 | 0.27 | 0.42 | 0.60 | 0.80 | 0.79 |
| | | Atomic concentration ratio C:O:Si | | | | | | |
| | | Reference | | | | | | Reference |
| (etch: 80 s) | | Example | Example | Example | Example | Example | Example | Example |
| Element | State | 3-2 | 3-5 | 3-4 | 3-3 | 3-2 | 3-1 | 3-1 |
| C | 1s | 0.98 | 0.85 | 0.64 | 0.46 | 0.32 | 0.14 | 0.05 |
| O | 1s | 0.02 | 0.07 | 0.09 | 0.11 | 0.08 | 0.08 | 0.12 |
| Si | 2p3/2 | 0.00 | 0.08 | 0.27 | 0.43 | 0.60 | 0.78 | 0.83 |

As the result of composition analysis by XPS, it was found that the composition of the surface of the release layer in each of samples of Examples 3-1 to 3-5 formed using the target in which a ratio of Si:C is Si:C=90:10 to 10:90 is SiₓC_{y}O_{z} (0.05≤x≤0.49, 0.15≤y≤0.73, 0.22≤z≤0.36, x+y+z=1). Further, it was found that nitrogen (N) is contained in an amount of 0.7 at % or less as inevitable impurities in the surface of the release layer.

### (3. Measurement of X-Ray Diffraction Pattern)

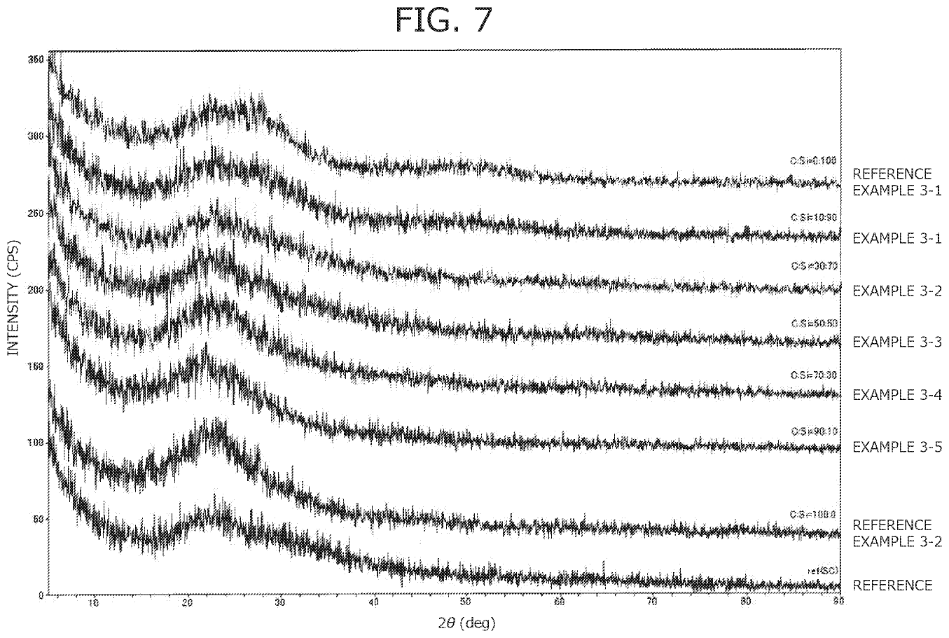

According to devices and conditions shown in Table 11, an X-ray diffraction (XRD) pattern of each sample was measured. The results are shown in FIG. 7. Herein, the polyimide substrate-attached resin laminate of Example 2-1 was used as reference. It was found that in any of the samples, the diffraction pattern shows a broad peak and the crystalline state of the release layer is an amorphous state.

TABLE 11

| | |
|---|---|
| Device | Smart Lab |
| | (manufactured by Rigaku Corporation) |
| X-ray output | 40 kV, 30 mA |
| Wavelength (1 Å = 10⁻¹⁰ m) | CuKa/1.541867 Å |
| Optical system | In-plane diffraction optical system |
| Scan mode | Continuous |
| Scan speed | 2°/min |
| Step interval | 0.04° |
| Scan axis | 2θχ/φ |
| Scan range | 5-90° |
| Incident parallel slit | In-plane_PSC_0.5deg |
| Incident slit | 0.2 mm |
| Length limiting slit | 10 mm |
| Receiving slit 1 | 20 mm |
| Receiving optical element | PSA_open |
| Receiving parallel slit | In-plane_PSA_0.5deg |
| Receiving slit 2 | 20 mm |
| Detector monochrometer | None |

### (4. Measurement of Spectral Properties)

The transmissivity, the reflectance, and the absorptance of each sample were measured and the absorptance of only the release layer was calculated. In measurement of spectral properties, measurement was performed in a wavelength region from 300 nm to 400 nm an incident angel θ=12° using a spectrophotometer (U-4100 manufactured by Hitachi, Ltd.).

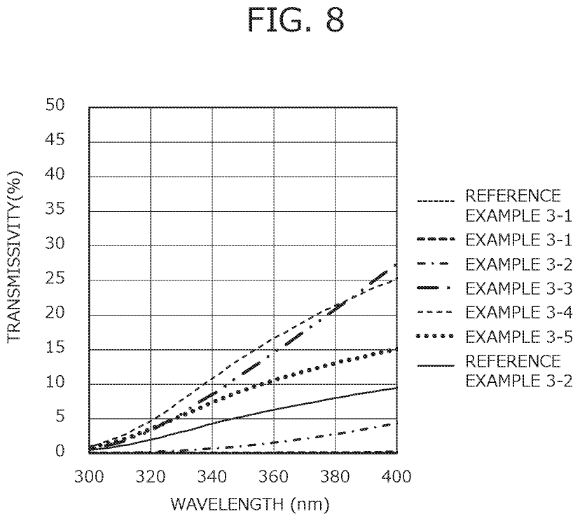

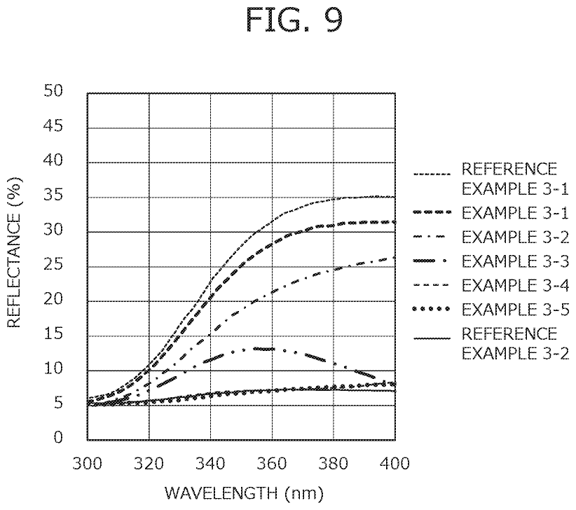

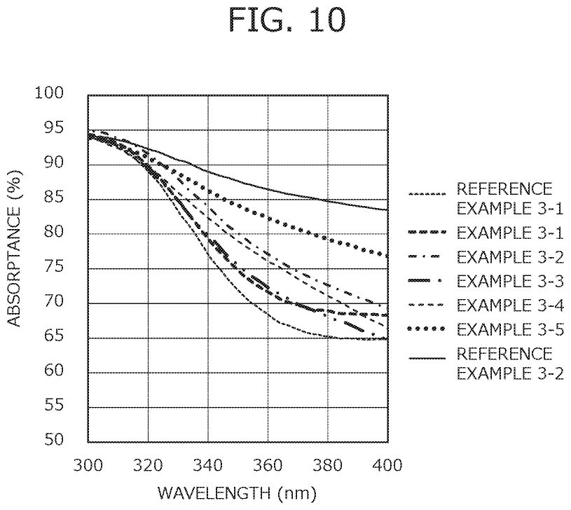

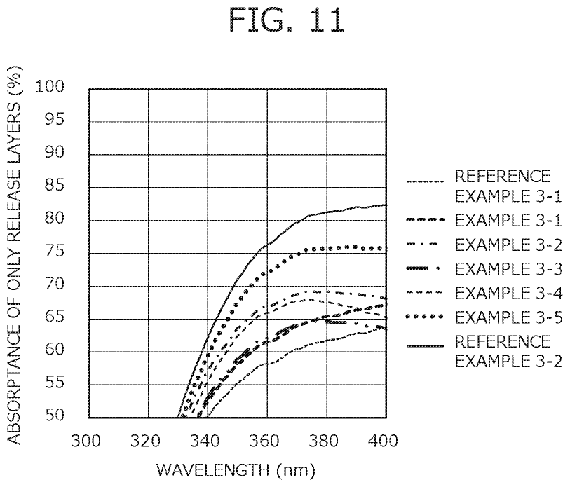

The results are shown in FIG. 8 (transmissivity), FIG. 9 (reflectance), FIG. 10 (absorptance), and FIG. 11 (absorptance of only the release layer).

As the result of the measurement of spectral properties, it was found that in Examples 3-1 to 3-5, the absorptance of only the release layer in a wavelength region having a wavelength of 340 nm or more and 400 nm or less is 50% or more. That is, the release layer in Examples 3-1 to 3-5 favorably absorbs ultraviolet light (for example, wavelength: 355 nm) used in the releasing step.

### (5. Release Test by Laser Beam Irradiation)

The results obtained by performing a release test using each sample while the laser beam intensity is changed are shown in Table 12.

TABLE 12

| | | 100 mJ/cm² | | | 90 mJ/cm² | | | 80 mJ/cm² | | | 70 mJ/cm² | | |
|---|---|---|---|---|---|---|---|---|---|---|---|---|---|
| | | | Change | | | Change | | | Change | | | Change | |
| | Release | | in | | | in | | | in | | | in | |
| | layer | | color | | | color | | | color | | | color | |
| | Si—C | | of | | | of | | | of | | | of | |
| | mixing | | release | | | release | | | release | | | release | |
| Sample | ratio | Releasability | layer | Ash | Releasability | layer | Ash | Releasability | layer | Ash | Releasability | layer | Ash |
| Reference | Si:C = 100:0 | ⊙ | Yes | Yes | ⊙ | Yes | Yes | ⊙ | No | Yes | ⊙ | No | Yes |
| Example | | | | | | | | | | | | | |
| 3-1 | | | | | | | | | | | | | |
| Example | Si:C = 90:10 | ⊙ | Yes | Yes | ⊙ | No | Yes | ⊙ | No | Yes | ⊙ | No | No |
| 3-1 | | | | | | | | | | | | | |
| Example | Si:C = 70:30 | ⊙ | Yes | No | ⊙ | Yes | No | ⊙ | Yes | No | ∘ | No | No |
| 3-2 | | | | | | | | | | | | | |
| Example | Si:C = 50:50 | ⊙ | Yes | No | ⊙ | Yes | No | ⊙ | No | No | ∘ | No | No |
| 3-3 | | | | | | | | | | | | | |
| Example | Si:C = 30:70 | ⊙ | Yes | No | ⊙ | Yes | No | ⊙ | No | No | ∘ | No | No |
| 3-4 | | | | | | | | | | | | | |
| Example | Si:C = 10:90 | ⊙ | Yes | No | ⊙ | Yes | No | ∘ | No | No | ∘ | No | No |
| 3-5 | | | | | | | | | | | | | |
| Reference | Si:C = 0:100 | ⊙ | Yes | Yes | ⊙ | Yes | Yes | ∘ | Yes | Yes | Δ | No | No |
| Example | | | | | | | | | | | | | |
| 3-2 | | | | | | | | | | | | | |

From this result, it was found that when the ratio of Si:C in the target when the release layer is formed is in a range of Si:C=10:90 to 90:10 and the composition ratio of the release layer is in a range of SiₓC_{y}O_{z} (0.05≤x≤0.49, 0.15≤y≤0.73, 0.22≤z≤0.36, x+y+z=1), the resin substrate can be favorably released without damages by low energy having a laser beam intensity of 70 to 100 mJ/cm².

Further, it was found that when the ratio of Si:C in the target when the release layer is formed is in a range of Si:C=10:90 to 30:70 and the composition ratio of the release layer is in a range of SiₓC_{y}O_{z} (0.05≤x≤0.43, 0.27≤y≤0.73, 0.22≤z≤0.30, x+y+z=1), ashes are not generated at a laser beam intensity of 70 to 100 mJ/cm².

Furthermore, it was found that when the ratio of Si:C in the target when the release layer is formed is in a range of Si:C=10:90 to 50:50 and the composition ratio of the release layer is in a range of SiₓC_{y}O_{z}(0.05≤x≤0.35, 0.43≤y≤0.73, 0.22≤z≤0.23, x+y+z=1), ashes and change in color of the release layer are not generated at a laser beam intensity of 70 to 80 mJ/cm².

### REFERENCE SIGNS LIST

S: RESIN SUBSTRATE LAMINATE
   1: SUPPORT SUBSTRATE
      1a: FIRST SURFACE
      1b: SECOND SURFACE
   2: RELEASE LAYER
      2a: RELEASE LAYER SURFACE
   3: RESIN SUBSTRATE
      3a: FIRST SURFACE
      3b: SECOND SURFACE
   4: RELEASE LAYER-ATTACHED SUPPORT SUBSTRATE
   P: ELECTRONIC DEVICE MEMBER
SP: ELECTRONIC DEVICE MEMBER-ATTACHED LAMINATE
D: ELECTRONIC DEVICE

1. A resin substrate laminate comprising:
a support substrate;
a release layer-attached support substrate which has a release layer laminated on the support substrate; and
a resin substrate which is releasably laminated on a surface, which is opposite to the support substrate, of the release layer, wherein
a composition of a surface of the release layer is SiₓC_{y}O_{z} (0.05≤x≤0.43, 0.27≤y≤0.73, 0.22≤z≤0.30, x+y+z=1), and
the release layer is in an amorphous state and is formed by a material which enables the resin substrate to be released from the release layer by irradiation of a laser beam having a wavelength of 355 nm at an intensity of 60 to 80 mJ/cm².

2-5. (canceled)

6. A method for manufacturing an electronic device, the method comprising:
a step of preparing a resin substrate laminate by laminating a release layer on a support substrate using a target having a ratio of Si:C of 10:90 to 70:30 and laminating a resin substrate on a surface, which is opposite to the support substrate, of the release layer,
a member forming step of forming an electronic device member on a surface of the resin substrate of the resin substrate laminate; and
a releasing step of releasing the resin substrate from the release layer by irradiating the release layer that is in an amorphous state with a laser beam having a wavelength of 355 nm at an intensity of 60 to 80 mJ/cm².

7-10. (canceled)
